(19) United States
(12) Patent Application Publication
(10) Pub. No.: US 2020/0011918 A1
(43) Pub. Date: Jan. 9, 2020

(54) METHOD AND SYSTEM FOR QUICKLY DETECTING CATHODE SHORT CIRCUIT

(71) Applicant: NORTH CHINA UNIVERSITY OF TECHNOLOGY, Beijing (CN)

(72) Inventors: Jun TIE, Beijing (CN); Rentao ZHAO, Beijing (CN); Zhifang ZHANG, Beijing (CN); Wentang ZHENG, Beijing (CN)

(73) Assignee: NORTH CHINA UNIVERSITY OF TECHNOLOGY, Beijing (CN)

(21) Appl. No.: 16/460,059

(22) Filed: Jul. 2, 2019

(30) Foreign Application Priority Data
Jul. 3, 2018 (CN) 201810716155.3

(51) Int. Cl. G01R 31/02

(52) U.S. Cl. CPC G01R 31/025

(57) ABSTRACT

The present invention discloses a method and system for quickly detecting a cathode short circuit. The method includes: continuously measuring a cathode current; determining whether an increased value of the cathode current in a set time is within a set range of the increased value; if the increased value is within the set range of the increased value, establishing a linear model according to a change of the cathode current with time, and calculating a slope and a determining coefficient according to the linear model; if the increased value is not within the set range of the increased value, determining that the cathode does not have a short circuit; determining whether the slope is within a set slope threshold range; if the slope is within the set slope threshold range, determining whether the determining coefficient is greater than a set determining coefficient threshold; if the slope is not within the set slope threshold range, determining that the cathode does not have a short circuit; if the determining coefficient is greater than or equal to the set determining coefficient threshold, determining that the cathode has a short circuit; and if the determining coefficient is smaller than the set determining coefficient threshold, determining that the cathode does not have a short circuit. The present invention can avoid a sustained short-circuit current loss and improve the electrolysis current efficiency.

This application claims priority to Chinese application number 201810716155.3, filed Jul. 3, 2018 with a title of METHOD AND SYSTEM FOR QUICKLY DETECTING CATHODE SHORT CIRCUIT. The above-mentioned patent application is incorporated herein by reference in its entirety.

### TECHNICAL FIELD

The present invention relates to the field of short circuit detection, and in particular to a method and system for quickly detecting a cathode short circuit.

### BACKGROUND

In the industrial production process of electrolytic refining and electrolytic deposition of aqueous solutions of metals such as copper, lead, zinc, nickel and manganese, generally, a single electrolytic cell contains tens of anodes and a corresponding number of cathodes, and anode plates and cathode plates are cross side by side. The anode and the cathode of the electrolytic cell are each in a plate shape and are thus called an anode plate and a cathode plate, with the area of each single face being 1 m² or more. A single electrode allows a current of 500 A or more to pass. Due to a narrow space between the anode and cathode on the electrolytic cell and an electrode distance of dozens of millimeters, local deformation on the electrode surface may cause uneven distribution of a current on the electrode surface, resulting in an increase in local current density; proportion or component disorder of additives in the electrolytic process causes the surface to form dendrites; for the anode used for refining, some components exceed the requirements, resulting in the formation of agglomerates on the surface of the corresponding cathode. The occurrence of these conditions will cause localized formation of the agglomerates on the surface of the cathode and the agglomerates will gradually grow into coarse particles. When the particles are in contact with the surface of the anode, a short circuit is formed between the cathode and the anode. At this time, the cathode current reaches a maximum which is three times the average current, which not only reduces current efficiency, but also reduces the cathode quality and even causes serious situations such as burning and deformation of the cathode plate and a current conducting rod.

At present, for the short circuit between the cathode and the anode, infrared imaging detection, drag meter detection, and water spray detection and the like are generally adopted. These methods can be used to detect the occurrence of the short circuit under the conditions that the short circuit has been formed between the anode and the cathode and the short-circuit current is up to 1000 A or above, resulting in remarkable heating of the conductive end of the cathode, and then the short circuit is cleaned, so the methods themselves have caused a loss of current and cathode quality.

### SUMMARY

An objective of the present invention is to provide a method and system for quickly detecting a cathode short circuit, which can diagnose a short circuit fault when a cathode short circuit just occurs, thereby avoiding a sustained short-circuit current loss.

To achieve the above purpose, the present invention provides the following technical solution.

A method for quickly detecting a cathode short circuit includes:

continuously measuring a cathode current;

determining whether an increased value of the cathode current in a set time is within a set range of the increased value to obtain a first determining result;

if the first determining result indicates that the increased value of the cathode current in the set time is within the set range of the increased value, drawing a curve according to the change of the cathode current with time, and calculating a slope and a determining coefficient of the curve according to the curve, the determining coefficient indicating the degree of fitting of the measured data of the cathode current to the curve;

if the first determining result indicates that the increased value of the cathode current in the set time is not within the set range of the increased value, determining that the cathode does not have a short circuit;

determining whether the slope is within a set slope threshold range, to obtain a second determining result;

if the second determining result indicates that the slope is within the set slope threshold range, determining whether the determining coefficient is greater than a set determining coefficient threshold, to obtain a third determining result;

if the second determining result indicates that the slope is not within the set slope threshold range, determining that the cathode does not have a short circuit;

if the third determining result indicates that the determining coefficient is greater than or equal to the set determining coefficient threshold, determining that the cathode has a short circuit; and

if the third determining result indicates that the determining coefficient is smaller than the set determining coefficient threshold, determining that the cathode does not have a short circuit.

Optionally, the sampling frequency of the cathode current is greater than or equal to 1/60 Hz.

Optionally, the increased value of the cathode current in the set time is the difference between a current value of the current at the set time and a current value at the start.

Optionally, the range of the set time is 5-20 min.

Optionally, the set range of the increased value is 50-1500 A.

Optionally, the slope threshold range is 10-60 A/min.

Optionally, the set determining coefficient threshold is 0.7.

To achieve the above purpose, the present invention further provides the following technical solution.

A system for quickly detecting a cathode short circuit includes:

a measuring module, configured to continuously measure a cathode current;

a first determining module, configured to determine whether an increased value of the cathode current in a set time is within a set range of the increased value to obtain a first determining result;

a calculation module, configured to, if the first determining result indicates that the increased value of the cathode current in the set time is within the set range of the increased value, establish a linear model according to a change of the cathode current with time, and calculate a slope and a determining coefficient according to the linear model; and

if the first determining result indicates that the increased value of the cathode current in the set time is not within the set range of the increased value, determining that the cathode does not have a short circuit;

a second determining module, configured to determine whether the slope is within a set slope threshold range, to obtain a second determining result;

a third determining module, configured to, if the second determining result indicates that the slope is within the set slope threshold range, determine whether the determining coefficient is greater than a set determining coefficient threshold, to obtain a third determining result; and

if the second determining result indicates that the slope is not within the set slope threshold range, determining that the cathode does not have a short circuit; and

a short circuit determining module, configured to, if the third determining result indicates that the determining coefficient is greater than or equal to the set determining coefficient threshold, determine that the cathode has a short circuit; and

if the third determining result indicates that the determining coefficient is smaller than the set determining coefficient threshold, determine that the cathode does not have a short circuit.

Optionally, the system further includes:

a prompting module, configured to prompt that the cathode has a short circuit.

According to a specific embodiment provided by the present invention, the present invention discloses the following technical effects: The present invention provides a method for quickly detecting a cathode short circuit, including: continuously measuring a cathode current; determining whether an increased value of the cathode current in a set time is within a set range of the increased value; if the increased value of the cathode current in the set time is within the set range of the increased value, establishing a linear model according to a change of the cathode current with time, and calculating a slope and a determining coefficient according to the linear model; if the increased value of the cathode current in the set time is not within the set range of the increased value, determining that the cathode does not have a short circuit; determining whether the slope is within a set slope threshold range; if the slope is within the set slope threshold range, determining whether the determining coefficient is greater than a set determining coefficient threshold; if the slope is not within the set slope threshold range, determining that the cathode does not have a short circuit; if the determining coefficient is greater than or equal to the set determining coefficient threshold, determining that the cathode has a short circuit; and if the determining coefficient is smaller than the set determining coefficient threshold, determining that the cathode does not have a short circuit. In the present invention, the change of the cathode current with time, which is obtained by continuous measurement, is processed, and a short circuit fault can be diagnosed when a cathode short circuit just occurs, thereby avoiding a sustained short-circuit current loss, and improving the electrolysis current efficiency.

### BRIEF DESCRIPTION OF THE DRAWINGS

To describe the technical solutions in the embodiments of the present invention or in the prior art more clearly, the following briefly introduces the accompanying drawings required for describing the embodiments. Apparently, the accompanying drawings in the following description show merely some embodiments of the present invention, and a person of ordinary skill in the art may still derive other drawings from these accompanying drawings without creative efforts.

FIG. 1 is a flow chart of a method for quickly detecting a cathode short circuit according to an embodiment of the present invention; and

FIG. 2 is a structural view of a system for quickly detecting a cathode short circuit according to an embodiment of the present invention.

### DETAILED DESCRIPTION

The following clearly and completely describes the technical solutions in the embodiments of the present invention with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention without creative efforts shall fall within the protection scope of the present invention.

To make objectives, features, and advantages of the present invention more comprehensible, the following describes the present invention in more detail with reference to accompanying drawings and specific implementations.

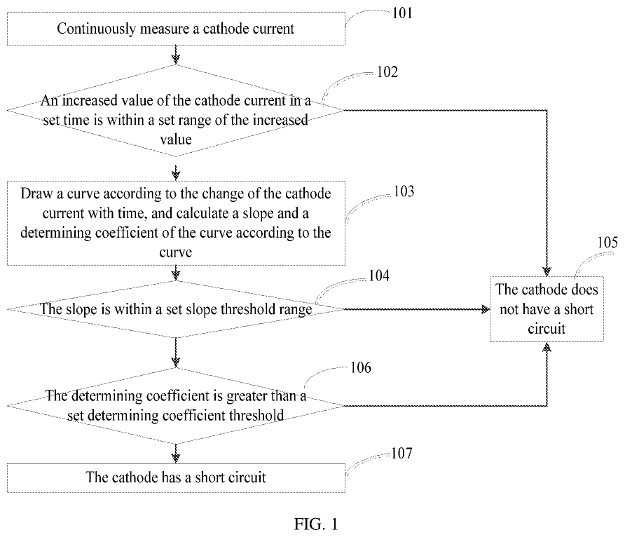

FIG. 1 is a flow chart of a method for quickly detecting a cathode short circuit according to an embodiment of the present invention. As shown in FIG. 1, the method for quickly detecting a cathode short circuit includes:

Step 101: continuously measure a cathode current, where the sampling frequency of the cathode current is 1/60 Hz.

Step 102: determine whether an increased value of the cathode current in a set time is within a set range of the increased value to obtain a first determining result, where the increased value of the cathode current in the set time is the difference between a current value of the current at the set time and a current value at the start, the range of the set time is 5 min, and the set range of the increased value is 50-300 A.

Step 103: if the first determining result indicates that the increased value of the cathode current in the set time is within the set range of the increased value, draw a curve according to the change of the cathode current with time, and calculate a slope and a determining coefficient of the curve according to the curve; where the expression of the curve is:

\hat{l}=\hat{l}₀+\hat{k}t (1)

where \hat{l} is an estimated value of a fitting curve; \hat{l} is a constant of the curve; \hat{k} is the slope of the change of the curve current with time; and t is time. The calculation formula of \hat{k} is as follows:

$$k = \frac{{\sum }_{i = 1}^{100} ( {t}_{i} - \overline{t} ) ( {I}_{i} - \overline{I} )}{{\sum }_{i = 1}^{100} {( {t}_{i} - \overline{t} )}^{2}} \qquad ( 2 )$$

At the same time, calculate the determining coefficient R², which indicates the degree of fitting of the measured data to the curve, with the calculation formula being:

$${R}^{2} = \frac{{\sum }_{i = 1}^{100} {( {\hat{I}}_{i} - \overline{I} )}^{2}}{{\sum }_{i = 1}^{100} {( {I}_{i} - \overline{I} )}^{2}} \qquad ( 3 )$$

In formulas (2) and (3), t̅ and l̅ are averages of the time and the current, respectively.

Step 104: determine whether the slope is within a set slope threshold range, to obtain a second determining result, where the slope threshold range is 10-60 A/min.

Step 105: if the first determining result indicates that the increased value of the cathode current in the set time is not within the set range of the increased value, determine that the cathode does not have a short circuit.

Step 106: if the second determining result indicates that the slope is within the set slope threshold range, determine whether the determining coefficient is greater than a set determining coefficient threshold, to obtain a third determining result; and

if the second determining result indicates that the slope is not within the set slope threshold range, determine that the cathode does not have a short circuit.

Step 107: if the third determining result indicates that the determining coefficient is greater than or equal to the set determining coefficient threshold, determine that the cathode has a short circuit, where the set determining coefficient threshold is 0.7; and

if the third determining result indicates that the determining coefficient is smaller than the set determining coefficient threshold, determine that the cathode does not have a short circuit.

In the present invention, the change of the cathode current with time is obtained by continuous measurement and processed, so that a cathode short circuit is quickly detected, and a short circuit fault can be diagnosed when the cathode short circuit just occurs, thereby avoiding a sustained short-circuit current loss, and improving the electrolysis current efficiency.

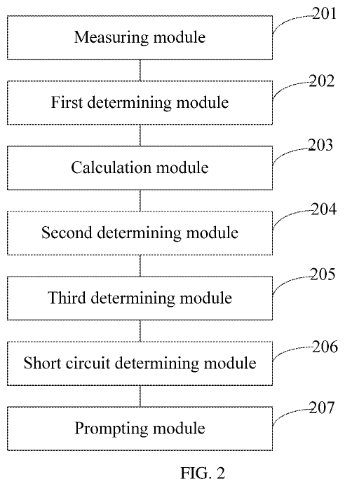

FIG. 2 is a structural view of a system for quickly detecting a cathode short circuit according to an embodiment of the present invention. As shown in FIG. 2, the system for quickly detecting a cathode short circuit includes:

a measuring module 201, configured to continuously measure a cathode current;

a first determining module 202, configured to determine whether an increased value of the cathode current in a set time is within a set range of the increased value to obtain a first determining result;

a calculation module 203, configured to, if the first determining result indicates that the increased value of the cathode current in the set time is within the set range of the increased value, establish a linear model according to a change of the cathode current with time, and calculate a slope and a determining coefficient according to the linear model; and

if the first determining result indicates that the increased value of the cathode current in the set time is not within the set range of the increased value, determine that the cathode does not have a short circuit;

a second determining module 204, configured to determine whether the slope is within a set slope threshold range, to obtain a second determining result;

a third determining module 205, configured to, if the second determining result indicates that the slope is within the set slope threshold range, determine whether the determining coefficient is greater than a set determining coefficient threshold, to obtain a third determining result; and

if the second determining result indicates that the slope is not within the set slope threshold range, determine that the cathode does not have a short circuit; and

a short circuit determining module 206, configured to, if the third determining result indicates that the determining coefficient is greater than or equal to the set determining coefficient threshold, determine that the cathode has a short circuit; and

if the third determining result indicates that the determining coefficient is smaller than the set determining coefficient threshold, determine that the cathode does not have a short circuit.

The system further includes:

a prompting module 207, configured to prompt that the cathode has a short circuit.

Each embodiment of the present specification is described in a progressive manner, each embodiment focuses on the difference from other embodiments, and the same and similar parts between the embodiments may refer to each other. For a system disclosed in the embodiments, since it corresponds to the method disclosed in the embodiments, the description is relatively simple, and reference can be made to the method description.

Several examples are used for illustration of the principles and implementation methods of the present invention. The description of the embodiments is used to help illustrate the method and its core principles of the present invention. In addition, those skilled in the art can make various modifications in terms of specific embodiments and scope of application in accordance with the teachings of the present invention. In conclusion, the content of this specification shall not be construed as a limitation to the present invention.

What is claimed is:

1. A method for quickly detecting a cathode short circuit, comprising:
continuously measuring a cathode current;
determining whether an increased value of the cathode current in a set time is within a set range of the increased value to obtain a first determining result;
if the first determining result indicates that the increased value of the cathode current in the set time is within the set range of the increased value, drawing a curve according to the change of the cathode current with time, and calculating a slope and a determining coefficient of the curve according to the curve, the determining coefficient indicating the degree of fitting of the measured data of the cathode current to the curve;
if the first determining result indicates that the increased value of the cathode current in the set time is not within the set range of the increased value, determining that the cathode does not have a short circuit;
determining whether the slope is within a set slope threshold range, to obtain a second determining result;
if the second determining result indicates that the slope is within the set slope threshold range, determining whether the determining coefficient is greater than a set determining coefficient threshold, to obtain a third determining result;
if the second determining result indicates that the slope is not within the set slope threshold range, determining that the cathode does not have a short circuit;
if the third determining result indicates that the determining coefficient is greater than or equal to the set determining coefficient threshold, determining that the cathode has a short circuit; and
if the third determining result indicates that the determining coefficient is smaller than the set determining coefficient threshold, determining that the cathode does not have a short circuit.

2. The method for quickly detecting a cathode short circuit according to claim 1, wherein the sampling frequency of the cathode current is greater than or equal to 1/60 Hz.

3. The method for quickly detecting a cathode short circuit according to claim 1, wherein the increased value of the cathode current in the set time is the difference between a current value of the current at the set time and a current value at the start.

4. The method for quickly detecting a cathode short circuit according to claim 1, wherein the range of the set time is 5-20 min.

5. The method for quickly detecting a cathode short circuit according to claim 1, wherein the set range of the increased value is 50-1500 A.

6. The method for quickly detecting a cathode short circuit according to claim 1, wherein the slope threshold range is 10-60 A/min.

7. The method for quickly detecting a cathode short circuit according to claim 1, wherein the set determining coefficient threshold is 0.7.

8. A system for quickly detecting a cathode short circuit, comprising:
a measuring module, configured to continuously measure a cathode current;
a first determining module, configured to determine whether an increased value of the cathode current in a set time is within a set range of the increased value to obtain a first determining result;
a calculation module, configured to, if the first determining result indicates that the increased value of the cathode current in the set time is within the set range of the increased value, establish a linear model according to a change of the cathode current with time, and calculate a slope and a determining coefficient according to the linear model; and
if the first determining result indicates that the increased value of the cathode current in the set time is not within the set range of the increased value, determining that the cathode does not have a short circuit;
a second determining module, configured to determine whether the slope is within a set slope threshold range, to obtain a second determining result;
a third determining module, configured to, if the second determining result indicates that the slope is within the set slope threshold range, determine whether the determining coefficient is greater than a set determining coefficient threshold, to obtain a third determining result; and
if the second determining result indicates that the slope is not within the set slope threshold range, determining that the cathode does not have a short circuit; and
a short circuit determining module, configured to, if the third determining result indicates that the determining coefficient is greater than or equal to the set determining coefficient threshold, determine that the cathode has a short circuit; and
if the third determining result indicates that the determining coefficient is smaller than the set determining coefficient threshold, determine that the cathode does not have a short circuit.

9. The system for quickly detecting a cathode short circuit according to claim 1, further comprising:
a prompting module, configured to prompt that the cathode has a short circuit.
